(19) United States
(12) Patent Application Publication
(10) Pub. No.: US 2025/0255078 A1
(43) Pub. Date: Aug. 7, 2025

(54) LIGHT EMITTING DEVICES INCLUDING A QUANTUM DOT COLOR CONVERSION MATERIAL AND METHOD OF MAKING THEREOF

(71) Applicant: Shoei Chemical Inc., Tokyo (JP)

(72) Inventors: SAKET CHADDA, MILPITAS, CA (US); RAVISUBHASH TANGIRALA, MILPITAS, CA (US); IVAN HUANG, MILPITAS, CA (US); DAVID OLMEIJER, MILPITAS, CA (US)

(21) Appl. No.: 18/856,579

(22) PCT Filed: Apr. 12, 2023
(86) PCT No.: PCT/US2023/018311

§ 371 Date: Oct. 11, 2024

Related U.S. Application Data
(60) Provisional application No. 63/330,407, filed on Apr. 13, 2022.

(51) Int. Cl. H10H 29/851; H01L 25/075; H10H 29/01; H10H 29/24

(52) U.S. Cl. CPC H10H 29/8512; H01L 25/0753; H10H 29/0361; H10H 29/24; H10H 29/8514; H10H 29/8515

(57) ABSTRACT

A method of forming a light emitting device includes providing a free standing support containing a matrix material including first and second vias, depositing in the first vias a first photocurable quantum dot ink including first quantum dots suspended in a first photocurable polymer, illuminating the first photocurable quantum dot ink with ultraviolet radiation or blue light from first LEDs of an array of LEDs to crosslink the first photocurable polymer material in the first vias, depositing in the second vias a second photocurable quantum dot ink comprising second quantum dots suspended in a second photocurable polymer material, illuminating the second photocurable quantum dot ink with ultraviolet radiation or blue light from second LEDs of the array of LEDs to crosslink the second photocurable polymer material in the second vias, and attaching the free standing support to the array of LEDs after the illuminating.

### RELATED APPLICATION

This present application claims the benefit of priority from U.S. Provisional Patent Application Ser. No. 63/330,407, filed on Apr. 13, 2022, and the entire content of which is incorporated herein by reference.

### FIELD

This disclosure relates to light emitting devices, and particularly to light emitting diodes optically coupled with a color conversion material and methods of fabricating the same.

### BACKGROUND

Light emitting diodes (LEDs) are used in electronic displays, such as backlights in liquid crystal displays in laptops and televisions, and in augmented reality (AR) displays. Such AR displays fire projected to be very high ppi (2000-8000) with high resolution and small sizes of display, which use micro-LEDs having a width of 10 microns or less, such as 1-2 microns.

### SUMMARY

An embodiment method of forming a light emitting device includes providing a free standing support comprising a matrix material containing first and second vias, depositing in the first vias in the matrix material a first photocurable quantum dot ink comprising a first plurality of quantum dots suspended in a first photocurable polymer material, illuminating the first photocurable quantum dot ink with ultraviolet radiation or blue light from first light emitting diodes of an array of light emitting diodes to crosslink the first photocurable polymer material in the first vias, depositing in the second vias in the matrix material a second photocurable quantum dot ink comprising a second plurality of quantum dots suspended in a second photocurable polymer material, wherein the second plurality of quantum dots are configured to emit light of a different peak wavelength than the first plurality of quantum dots, illuminating the second photocurable quantum dot ink with ultraviolet radiation or blue light from second light emitting diodes of the array of light emitting diodes to crosslink the second photocurable polymer material in the second vias, and attaching the free standing support to the array of light emitting diodes after the steps of illuminating the first and the second photocurable quantum dot ink.

Another embodiment method of forming a light emitting device includes providing a plurality of light emitting diodes on a substrate such that the plurality of light emitting diodes is configured to emit blue light or ultraviolet radiation incident photons, providing a color conversion device comprising a color conversion material formed in a plurality of vias in a matrix material, positioning the color conversion device relative to the plurality of light emitting diodes such that each of the plurality of vias is located over a corresponding one of the plurality of light emitting diodes, wherein the color conversion material in each of the plurality of vias is configured to absorb the incident photons from the corresponding one of the plurality of light emitting diodes and to generate converted photons having a longer peak wavelength than a peak wavelength of the incident photons, and adjusting a position of the color conversion device relative to the plurality of light emitting diodes to thereby maximize an intensity of the converted photons having the longer peak wavelength.

An embodiment light emitting device includes a substrate, a plurality of light emitting diodes located on the substrate and configured to emit blue or ultraviolet radiation incident photons, and a color conversion device comprising a color conversion material located in a plurality of vias in a matrix material. Each of the plurality of vias is located over a corresponding one of the plurality of light emitting diodes such that the color conversion material in each of the plurality of vias is configured to absorb the incident photons from the corresponding one of the plurality of light emitting diodes and to generate converted photons having a longer peak wavelength than a peak wavelength of the incident photons, and the color conversion device is a free standing structure that is attached over the plurality of light emitting diodes.

### BRIEF DESCRIPTION OF THE DRAWINGS

FIG. 1 is a vertical cross-sectional view of an intermediate structure that may be used in the formation of a light emitting device, according to various embodiments.

FIG. 2 is a vertical cross-sectional view of a light emitting device, according to various embodiments.

FIG. 3 is a vertical cross-sectional view of an intermediate structure that may be used in the formation of a color conversion device, according to various embodiments.

FIG. 4 is a vertical cross-sectional view of a further intermediate structure that may be used in the formation of a color conversion device, according to a first embodiment.

FIG. 5 is a vertical cross-sectional view of a further intermediate structure that may be used in the formation of a color conversion device, according to the first embodiment.

FIG. 6 is a vertical cross-sectional view of a further intermediate structure that may be used in the formation of a color conversion device, according to the first embodiment.

FIG. 7 is a vertical cross-sectional view of a further intermediate structure that may be used in the formation of a color conversion device, according to the first embodiment.

FIG. 8 is a vertical cross-sectional view of a further intermediate structure that may be used in the formation of a color conversion device, according to the first embodiment.

FIG. 9 is a vertical cross-sectional view of a further intermediate structure that may be used in the formation of a color conversion device, according to the first embodiment.

FIG. 10 is a vertical cross-sectional view of a color conversion device, according to various embodiments.

FIG. 11 is a vertical cross-sectional view of a further intermediate structure that may be used in the formation of a color conversion device, according to a second embodiment.

FIG. 12 is a vertical cross-sectional view of a further intermediate structure that may be used in the formation of a color conversion device, according to the second embodiment.

FIG. 13 is a vertical cross-sectional view of a further intermediate structure that may be used in the formation of a color conversion device, according to the second embodiment.

FIG. 14 is a vertical cross-sectional view of a further intermediate structure that may be used in the formation of a color conversion device, according to the second embodiment.

FIG. 15 is a vertical cross-sectional view of a further intermediate structure that may be used in the formation of a color conversion device, according to the second embodiment.

FIG. 16 is a vertical cross-sectional view of a further intermediate structure that may be used in the formation of a color conversion device, according to the second embodiment.

FIG. 17 is a vertical cross-sectional view of a further intermediate structure that may be used in the formation of a color conversion device, according to various embodiments.

FIG. 18 is a vertical cross-sectional view of a further intermediate structure that may be used in the formation of a color conversion device, according to various embodiments.

FIG. 19 is a vertical cross-sectional view of a light emitting device in a first configuration, according to various embodiments.

FIG. 20 is a further vertical cross-sectional view of the light emitting device in a second configuration, according to various embodiments.

FIG. 21 is a further vertical cross-sectional view of the light emitting device in a third configuration, according to various embodiments.

FIG. 22 is a vertical cross-sectional view of the packaged light emitting device in a one configuration, according to various embodiments.

FIG. 23 is a vertical cross-sectional view of the packaged light emitting device in another configuration, according to various embodiments.

### DETAILED DESCRIPTION

A display device, such as a direct view display (e.g., an AR display), may be formed from an ordered array of pixels. Each pixel may include a set of subpixels that emit light at a respective peak wavelength. For example, a pixel may include a red subpixel, a green subpixel, and a blue subpixel. Each subpixel may include one or more light emitting diodes that emit light of a particular wavelength. A traditional arrangement is to have red, green, and blue (RGB) subpixels within each pixel. Each pixel may be driven by a backplane circuit such that any combination of colors within a color gamut may be shown on the display for each pixel. The display panel may be formed by a process in which LED subpixels are soldered to, or otherwise electrically attached to, a bond pad located on a backplane. The bond pad may be electrically driven by the backplane circuit and other driving electronics.

Various embodiments provide a light emitting device configured to create high efficiency red, green, blue, and/or other color pixelated light from a shorter wavelength excitation source using photonically pumped quantum dots. Embodiment micron-scale light emitting diodes (micro-LEDs) which have a length and width less than 10 microns, such as 1 to 2 microns, may be used in AR displays and other direct view display devices. This emerging technology offers high black levels by using individual LEDs at each pixel location of a display device. Further, each pixel may be configured to generate a single color of light. A backplane upon which individual LEDs may be attached may include a substrate (e.g., plastic, glass, semiconductor, etc.) with thin-film transistor (TFT) structures, silicon CMOS, or other driver circuitry that may be configured to apply a voltage or current to each LED independently. For example, the backplane may include TFTs on a glass or plastic substrate, or bulk silicon transistors (e.g., transistors in a CMOS configuration) on a bulk silicon substrate or on a silicon-on-insulator (SOI) substrate. While micro-LEDs are described in the embodiments below, it should be noted that other types of LEDs (e.g., nanowire or other nanostructure LEDs) or macro-LEDs having a size (e.g., width and length) greater than 10 microns may also be used instead of or in addition to the micro-LEDs.

In some embodiments, a size of each micro-LED may be smaller than a pitch of the pixels used in a particular display device, such as a direct view display device or another display device. For example, a 2000 to 8000 ppi AR display may have adjacent micro-LEDs spaced apart by less than one micron, such as by 0.6 to 0.7 microns. It is difficult to sequentially place a high number of different color micro-LEDs (e.g., sequentially placing red, green and blue emitting LEDs) onto adjacent RGB subpixel regions of the same pixel on the backplane with high accuracy.

Some embodiments of this disclosure include a photonic emitter based on a LED having an undoped GaN active region (e.g., a micro-LED having a GaN light emitting active layer) or a low indium doped InGaN active region (e.g., a micro-LED having a low indium content InGaN light emitting active layer) coupled with a photonically pumped color conversion material. Such LEDs may emit ultraviolet (UV) radiation or blue light having a peak emission wavelength in the UV radiation or blue light spectral region (e.g., 370 to 460 nm, such as 390 to 420 nm, for example 400 to 410 nm). As used herein, the blue light spectral region includes blue and violet colors as perceived by the human observer.

In one embodiment, the color conversion material may include quantum dots. The quantum dots may be configured to absorb photons generated by the monochrome LEDs and to generate various colors of light (e.g., red, green and blue) depending on the properties of the quantum dots (e.g., quantum dot size and material composition).

In the size regime (e.g., sizes less than 10 microns) used for augmented reality (AR) displays (e.g., smart glasses) and other applications, the use of UV or blue emitting LEDs and photonically pumped quantum dots to create various colors may provide display devices having better uniformity across the backplane. By placing all adjacent monochrome LEDs (e.g., either UV or blue LEDs) on the backplane at the same time (e.g., from the same growth substrate), the tight tolerances may be met easier than by sequentially placing adjacent red, green and blue LEDs into adjacent subpixels of the same RGB pixel. The embodiments of the present disclosure provide methods which permit improved alignment between the monochrome LEDs and the respective quantum dots in each color subpixel by using the monochrome LED array to manufacture and align the quantum dots in the subpixels.

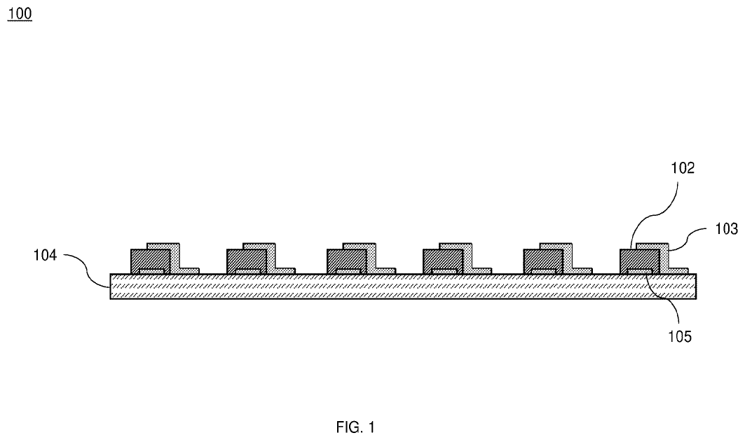

FIG. 1 is a vertical cross-sectional view of an intermediate structure 100 that may be used in the formation of a light emitting device, according to various embodiments. The intermediate structure 100 may include a plurality of LEDs 102 located on a substrate 104, such as a backplane. As described above, the LEDs 102 may have peak emission wavelength in the UV radiation range or in blue light spectral region (e.g., UV or blue emitting LEDs, also referred to as UV or blue LEDs).

In one embodiment, the LEDs 102 may have at least one first electrode 103 located on the top of the LED and facing away from the substrate 104. The first electrode 103 may be configured as an anode or a cathode electrode. In one embodiment, the LEDs 102 may be configured as vertical LEDs in which the second electrode 105 is located between the substrate 104 and the bottom of the LED 102. For example, the second electrode 105 may be bonded to a respective bonding pad on the substrate 104. In another embodiment, the LEDs 102 may contain a common transparent first electrode 103 (e.g., a transparent conductive oxide electrode) located over their light emitting side (e.g., top side in FIG. 1) and separate second electrodes 105 which control whether each LED 102 is turned on or off. In another embodiment, the LEDs may be configured as lateral LEDs in which both electrodes are located on the same side of the LED (e.g., on top or on bottom sides of the LED).

The substrate 104 may be a backplane having electrical circuitry (e.g., TFT and/or CMOS circuits) configured to supply voltages and currents to the LEDs 102 via the second electrodes 105 to thereby control light emission by the LEDs 102. A backplane may be an active or passive matrix backplane substrate for driving LEDs. As used herein, a “backplane substrate” refers to any substrate configured to affix multiple devices thereupon. In one embodiment, the backplane may include a substrate including silicon, glass, plastic, and/or at least other material that may provide structural support to devices attached thereto. In one embodiment, the backplane substrate may be a passive backplane substrate, in which metal interconnect structures (not shown) including metallization lines are present, for example, in a crisscross grid and dedicated active devices (e.g., TFTs) for each LED are not present. In another embodiment, the backplane substrate may be an active backplane substrate, which includes metal interconnect structures as a crisscross grid of conductive lines and further includes dedicated active devices (e.g., CMOS transistors or TFTs) for each LED at one or more intersections of the crisscross grid of conductive lines.

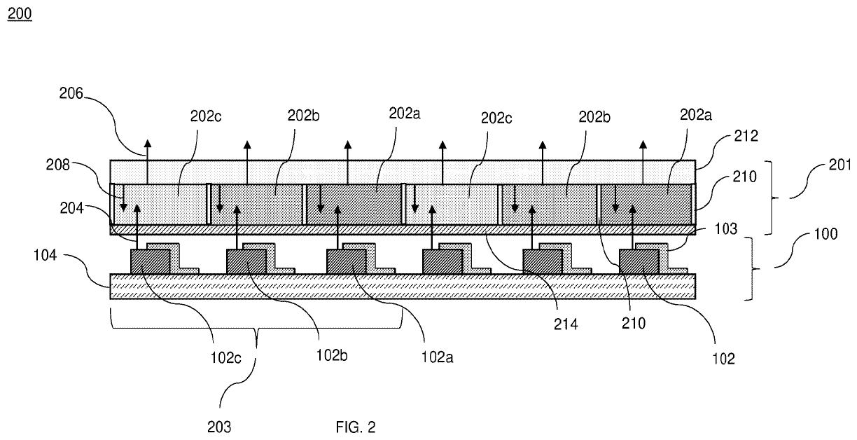

FIG. 2 is a vertical cross-sectional view of a light emitting device 200, according to various embodiments. The light emitting device 200 may include the intermediate structure 100 (e.g., see FIG. 1), which includes the substrate 104 and the plurality of LEDs (102, 102a, 102b, 102c) formed on the substrate 104. The second electrodes 105 are omitted from FIG. 2 for clarity. As described above, the LEDs 102 may be configured to emit blue or ultraviolet radiation incident photons 204. The light emitting device 200 may further include a color conversion device 201. In one embodiment, the color conversion device 201 is a freestanding device which is manufactured using the radiation emitted by the LEDs 102 of the intermediate structure 100. In other words, the color conversion device 201 is not deposited layer by layer on the intermediate structure 100, but is formed separately from the intermediate structure 100 such that it does not require the intermediate structure 100 for support. The completed color conversion device 201 is subsequently attached to the intermediate structure 100 using an adhesive and/or mechanical attachment to form the light emitting device 200.

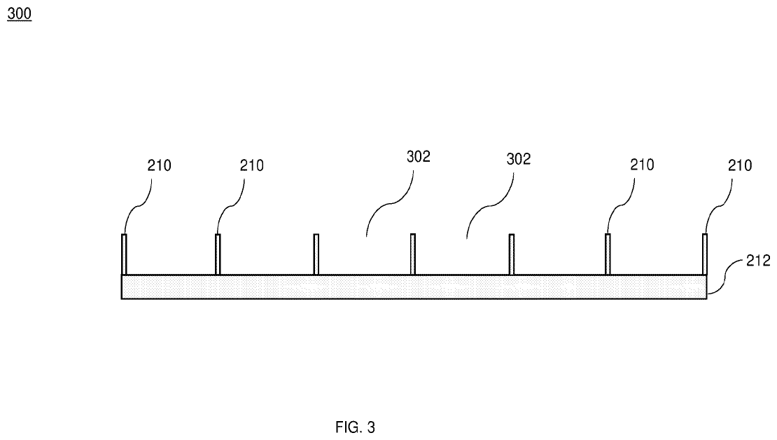

The color conversion device 201 includes a color conversion material (202a, 202b, 202c) formed in a plurality of vias 302 in a matrix material (as will be described with regard to FIG. 3 below). As described in greater detail below, the color conversion device 201 may optionally include a substrate 212 that supports a plurality of vias 302 that are bounded by matrix material walls 210. The substrate 212 and the walls 210 may be made of different materials or may be formed of the same material. The color conversion device 201 may further include an optional protective layer 214 that is transparent to the incident photons 204. The protective layer may comprise aluminum oxide or another transparent material.

The light emitting device 200 may be configured as an ordered array. For example, a first color conversion material 202a may be configured to absorb incident photons 204 and to generate converted photons 206 having a first color. Similarly, a second color conversion material 202b may be configured to absorb incident photons 204 and to generate converted photons 206 having a second color, and a third color conversion material 202c may be configured to absorb incident photons 204 and to generate converted photons 206 having a third color. A certain fraction of the incident photons 204 may be reflected by the substrate 212 to thereby become reflected photons 208. Reflected photons 208 may recirculate in the color conversion material (202a, 202b, 202c) and may thereby have an increased probability of being absorbed by the color conversion material (202a, 202b, 202c) and being transformed into converted photons 206. This process, which is sometimes called “photon recycling” may increase the quantum efficiency of the device.

In one embodiment, the light emitting device 200 may be configured as an ordered array of pixels with each pixel including a red subpixel, a green subpixel, and a blue subpixel. For example, a pixel 203 may include a first (e.g., red) subpixel having a first LED 102a and a corresponding first color (e.g., red) conversion material 202a, a second (e.g., green) subpixel having a second LED 102b and a corresponding second color (e.g., green) conversion material 202b, and a third (e.g., blue) subpixel having a third LED 102c and a third color (e.g., blue) conversion material 202c. In this way, the color conversion material (202a, 202b, 202c) in respective subpixels may be configured to respectively generate red, green, and blue converted photons 206. The light emitting device 200 may be organized an various other ways in further embodiments. For example, any number of LEDs 102 may be associated with color conversion materials that generate a single color. As such, each pixel may have a plurality of LEDs in each subpixel. Further, the various subpixels may not all have the same number of pixels. In one embodiment, the LEDs 102a, 102b, 102c may emit the same peak wavelength of radiation (e.g., UV or blue light). If the LEDs 102a, 102b, 102c emit blue light, then the third color (e.g., blue) conversion material 202c may be omitted from the blue subpixel.

Each of the plurality of vias 302 (see FIG. 3) may be located over a corresponding one of the plurality of LEDs (102a, 102b, 102c) such that the color conversion material (202a, 202b, 202c) in each of the plurality of vias is configured to absorb the incident photons 204 from the corresponding one of the plurality of LEDs 102 and to generate converted photons 206 having a longer peak wavelength than a peak wavelength of the incident photons 204. The substrate 212 (if present) is formed of a radiation transparent material such that converted photons 206 may be transmitted through the substrate 212.

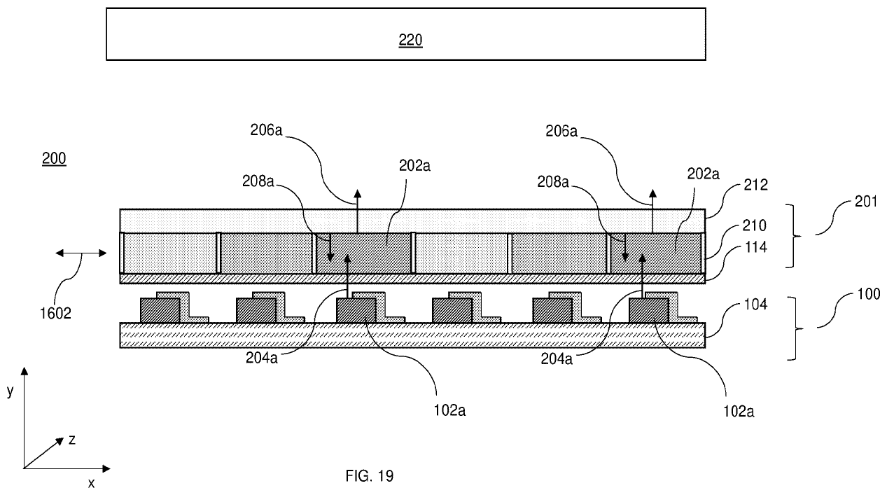

As shown in FIG. 2, the color conversion device 201 may be configured as a separate (i.e., free-standing) structure that is positioned over the plurality of LEDs 102. Further, as described in greater detail with reference to FIGS. 19 to 21 below, a position of the color conversion device 201 relative to the plurality of LEDs may be adjusted such that an intensity the converted photons 206 having the longer peak wavelength is maximized. Further, the plurality of LEDs 102 may comprise micro-LEDs each having a size (i.e., length and width) that is 10 microns or less, such as from approximately 1 to approximately 2 microns. Further, adjacent LEDs 102 may be separated by a distance that is 1 microns or less, such as from approximately 0.6 microns to approximately 0.7 microns.

The color conversion material (202a, 202b, 202c) may include quantum dots corresponding to various different colors. In this example, the color conversion material (202a, 202b, 202c) may include a plurality of first quantum dots 202a, a plurality of second quantum dots 202b, and a plurality of third quantum dots 202c, which may be configured to convert UV or blue incident photons 204 into photons having first, second, and third colors, respectively. For example, the first, second, and third colors may have different peak wavelengths in the red, green, and blue color spectrum range. The quantum dots may have a diameter in a range from approximately 1 nm to approximately 10 nm, such as in a range from 2 nm to 8 nm, and may be nanocrystals of a compound semiconductor material, such as a Group III-V semiconductor material (e.g., indium phosphide, as described in U.S. Pat. No. 9,884,763 B1, incorporated herein by reference in its entirety), a Group II-VI semiconductor material (e.g., ZnSe, ZnS, ZnTe, CdS, CdSe, etc., core-shell quantum dots, as described in U.S Patent Application Publication US 2017/0250322 A1, incorporated herein by reference in its entirety), and/or Group I-III-VI semiconductor material (e.g., AgInGaS/AgGaS core-shell quantum dots, as described in U.S. Pat. No. 10,927,294 B2, incorporated herein by reference in its entirety).

The quantum dots may emit different colored light (e.g., red, green or blue) depending on their diameter. The larger quantum dots may emit longer wavelength light while the smaller dots may emit shorter wavelength light. The quantum dots may be suspended in a material (e.g., a polymer such as polyimide) having a different (e.g., higher) index of refraction from that of the light extracting material 110. For example, the polyimide material may have a refractive index of 1.6 to 1.75, such as about 1.7. If blue LEDs 102 are used, then the blue light emitting quantum dots may be omitted.

Each of the LEDs 102 may be configured to emit incident photons 204 having a common wavelength or within a range of the target wavelengths. For example, GaN-based LEDs 102 may emit incident photons 204 having a wavelength that is in a range from approximately 370 nm to approximately 430 nm, such as approximately 400 nm to approximately 410 nm (i.e., in the blue or near-UV part of the electromagnetic spectrum). The LEDs 102 may exhibit a high degree of uniformity and may exhibit high efficiency.

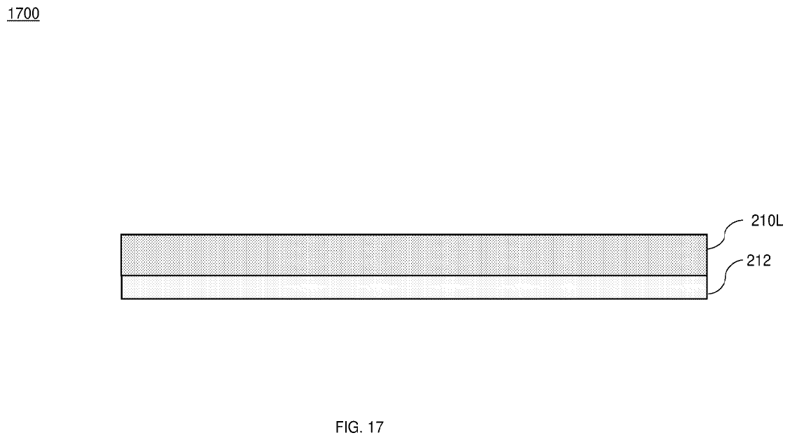

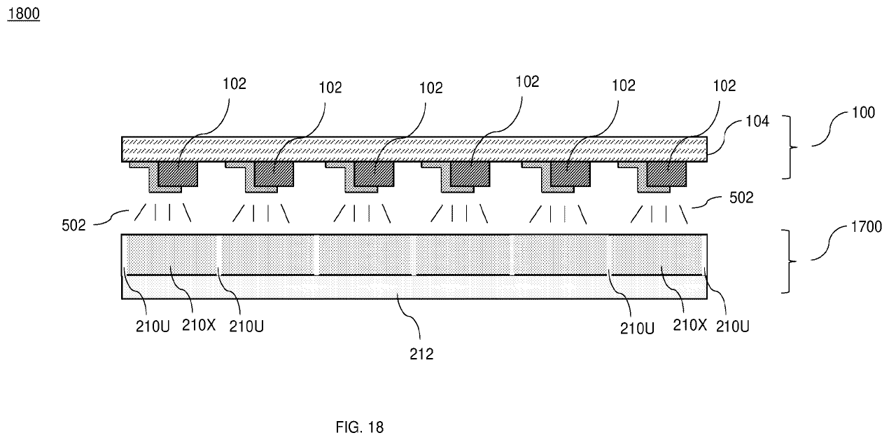

FIG. 3 is a vertical cross-sectional view of an intermediate structure 300 that may be used in the formation of a color conversion device 201 shown in FIG. 2, according to various embodiments. The intermediate structure 300 may include a free-standing support comprising a substrate 212 and a matrix material having a plurality of vias 302 formed therein. The vias 302 may be bounded by matrix material walls 210. The walls 210 and the substrate 212 may be formed of the same material. For example, the intermediate structure 300 may include a polymer material that is formed by an injection molding process. In other embodiments, the matrix material may include a positive-tone photosensitive polymer 210L formed over a substrate 212 (e.g., see FIG. 17 and related description, below). The vias 302 may be formed by selectively exposing portions of the positive-tone photosensitive polymer 210L to blue or UV radiation (e.g., see FIG. 18 and related description, below) that acts to generate un-crosslinked polymer material portions that may be removed with a solvent. Various other ways of forming vias 302 in a matrix material are contemplated within the scope of this disclosure.

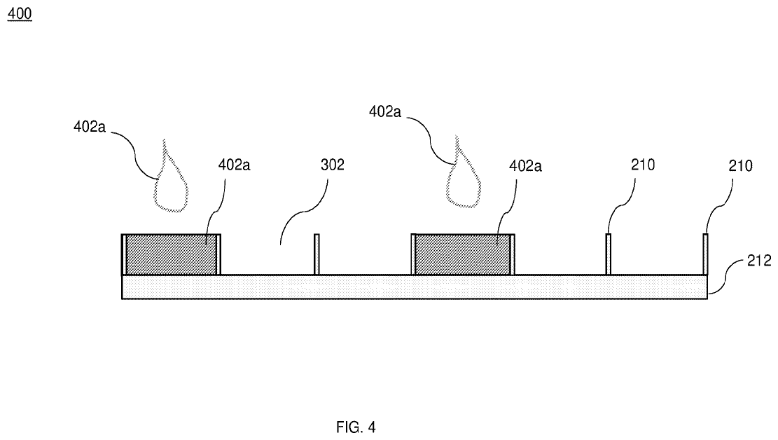

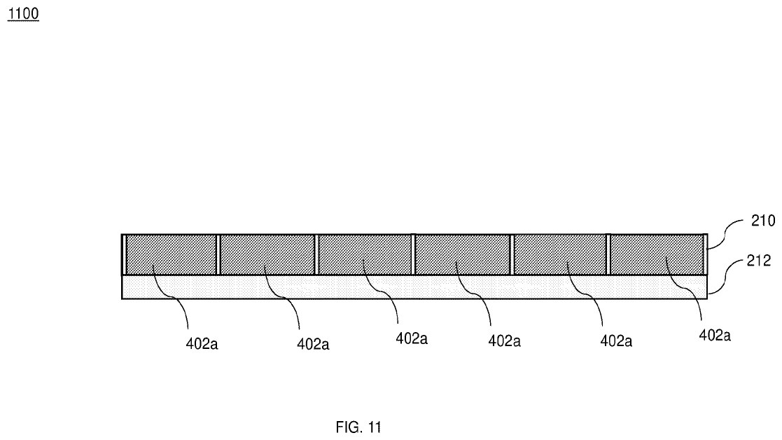

In a first embodiment illustrated in FIGS. 4-9, the quantum dot ink is selectively deposited in respective vias 302 followed by irradiation. In the second embodiment illustrated in FIGS. 11-16, the quantum dot ink is non-selectively deposited in respective vias 302 followed by irradiation.

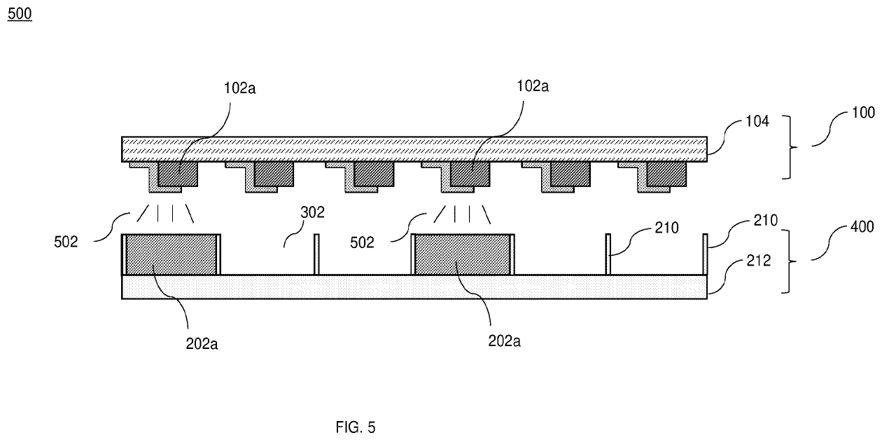

FIG. 4 is a vertical cross-sectional view of a further intermediate structure 400 that may be used in the formation of a color conversion device 201 (e.g., see FIG. 2), according to the first embodiment. In this embodiment, a first quantum dot ink 402a may be selectively introduced into a first plurality of vias 302 that are intended to contain the first quantum dots 202a. The first quantum dot ink 402a may include quantum dots having a first size and composition suspended in a photocurable polymer material. The first quantum dot ink 402a may be deposited in various ways. For example, the first quantum dot ink 402a may be deposited by an ink-jet printing process. The first quantum dot ink 402a may exposed to blue light or UV radiation to thereby crosslink the first photocurable polymer material, as described in greater detail with reference to FIG. 5 below.

FIG. 5 is a vertical cross-sectional view of a further intermediate structure 500 that may be used in the formation of a color conversion device 201 (e.g., see FIG. 2), according to the first embodiment. The intermediate structure 500 may include an array of LEDs (e.g., intermediate structure 100 of FIG. 1) positioned over the intermediate structure 400 of FIG. 4. While the array of LEDs is shown as being positioned above the intermediate structure 400 to irradiate the first quantum dot ink 402a, in an alternative embodiment, the array of LEDs may be positioned below the substrate 212 of the intermediate structure 400 to irradiate the first quantum dot ink 402a through the substrate 212. The array of LEDs may be used as a manufacturing tool to selectively illuminate the first quantum dot ink 402a. As shown, a first plurality of LEDs 102a may be selectively turned on to expose the first quantum dot ink 402a to blue light or UV radiation 502. In this way, the blue light or UV radiation 502 may cause the first quantum dot ink 402a to become crosslinked, thereby forming the first color conversion material 202a. Thus, the first LEDs 102a (e.g., LEDs located in red subpixels in the final device 201) may be used to expose the first quantum dot ink 402a to form the first (e.g., red) color conversion material 202a in the red subpixels.

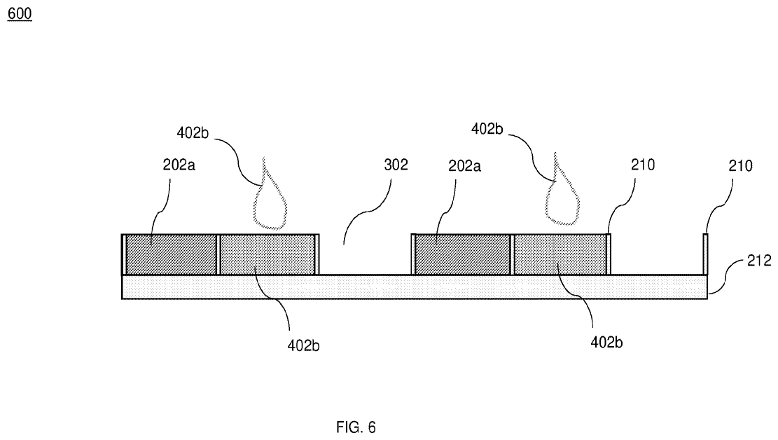

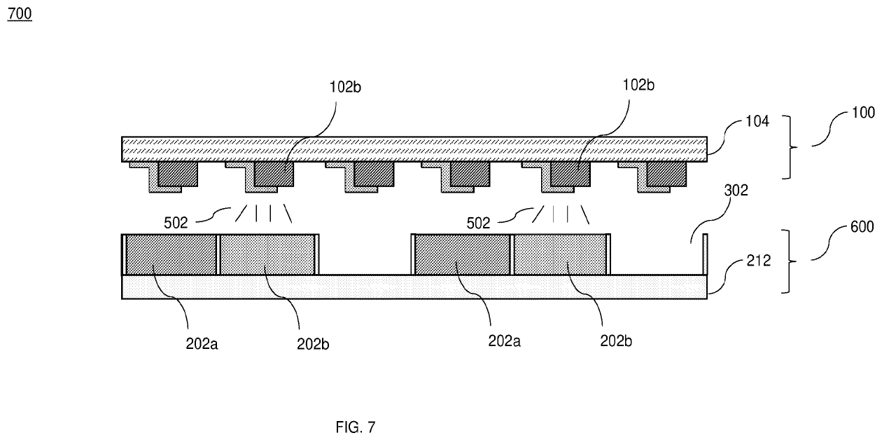

FIG. 6 is a vertical cross-sectional view of a further intermediate structure 600 that may be used in the formation of a color conversion device 201 (e.g., see FIG. 2), according to the first embodiment. A second quantum dot ink 402b may be introduced into a second plurality of vias 302, as shown. The second quantum dot ink 402b may include quantum dots having a second size and composition different from the first size and/or composition, suspended in a photocurable polymer material. The second quantum dot ink 402b may exposed to blue light or UV radiation to thereby crosslink the second photocurable polymer material, as described in greater detail with reference to FIG. 7, below.

FIG. 7 is a vertical cross-sectional view of a further intermediate structure 700 that may be used in the formation of a color conversion device 201 (e.g., see FIG. 2), according to the first embodiment. The intermediate structure 700 may include an array of LEDs (e.g., intermediate structure 100 of FIG. 1) positioned over or under the intermediate structure 600 of FIG. 6. As shown, a second plurality of LEDs 102b may be selectively turned on to expose the second quantum dot ink 402b to blue light or UV radiation 502. In this way, the blue light or UV radiation 502 may cause the second quantum dot ink 402b to become crosslinked, thereby forming the second color conversion material 202b. Thus, the second LEDs 102b (e.g., LEDs located in green subpixels in the final device 201) may be used to expose the second quantum dot ink 402b to form the second (e.g., green) color conversion material 202b in the green subpixels.

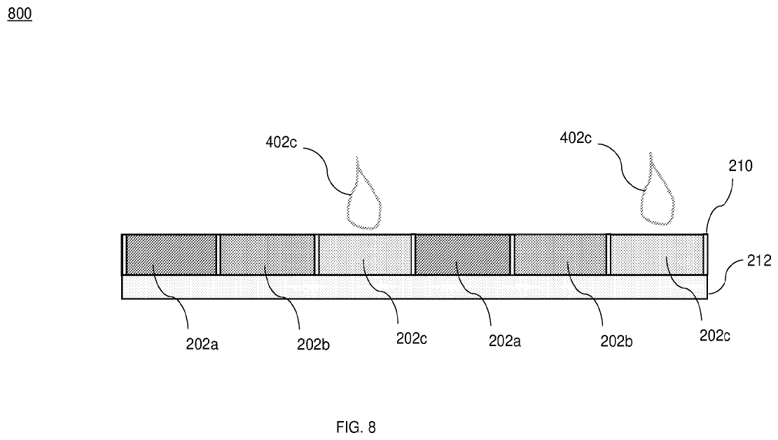

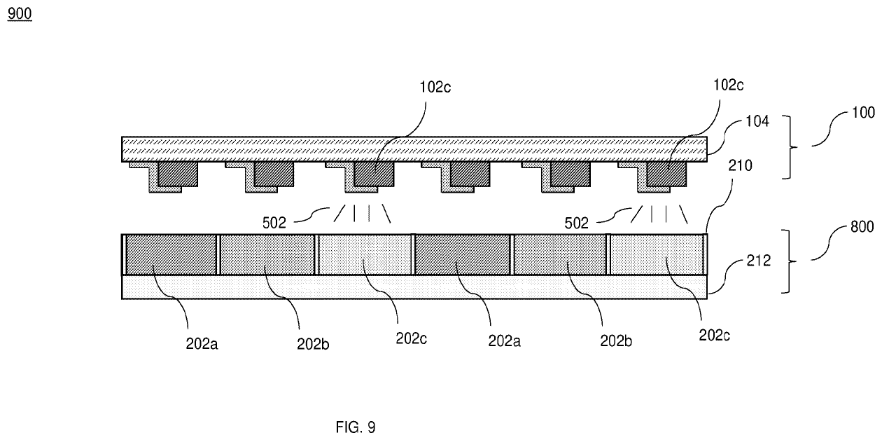

FIG. 8 is a vertical cross-sectional view of a further intermediate structure 800 that may be used in the formation of a color conversion device 201 (e.g., see FIG. 2), according to the first embodiment. If the third color conversion material 202c is present in the final device 201, then a third quantum dot ink 402c may be introduced into a third plurality of vias 302 (e.g., see FIG. 3), as shown. The third quantum dot ink 402c may include quantum dots having a third size and composition different from the first and the second size and/or composition, suspended in a photocurable polymer material. The third quantum dot ink 402c may exposed to blue light or UV radiation to thereby crosslink the third photocurable polymer material, as described in greater detail with reference to FIG. 9, below.

FIG. 9 is a vertical cross-sectional view of a further intermediate structure 900 that may be used in the formation of a color conversion device 201 (e.g., see FIG. 2), according to the first embodiment. The intermediate structure 900 may include an array of LEDs (e.g., intermediate structure 100 of FIG. 1) positioned over or under the intermediate structure 800 of FIG. 8. As shown, a third plurality of LEDs 102c may be selectively turned on to expose the third quantum dot ink 402c to blue light or UV radiation 502. In this way, the blue light or UV radiation 502 may cause the third quantum dot ink 402c to become crosslinked, thereby forming the third color conversion material 202c. Thus, the third LEDs 102c (e.g., LEDs located in blue subpixels in the final device 201) may be used to expose the third quantum dot ink 402c to form the third (e.g., blue) color conversion material 202c in the blue subpixels. Alternatively, if the LEDs 102 comprise blue LEDs, then the steps of FIGS. 8 and 9 may be omitted.

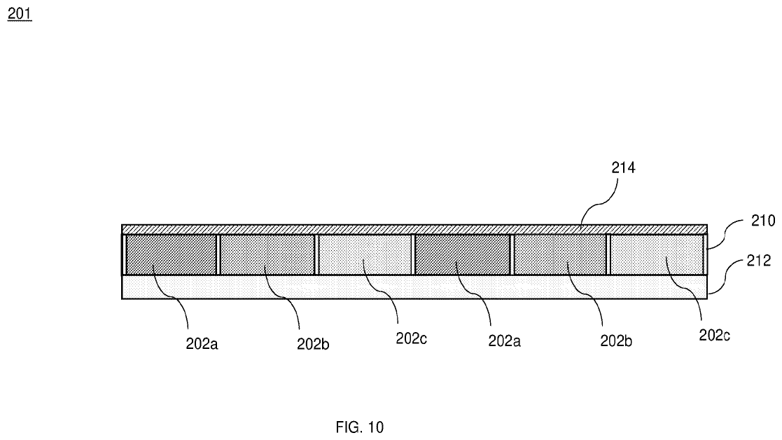

FIG. 10 is a vertical cross-sectional view of a color conversion device 201 (e.g., see FIG. 2), according to various embodiments. As shown, the color conversion device 201 may further include a protective layer 214 formed over the color conversion material (202a, 202b, 202c). In one embodiment, the protective layer 214 may be a thin layer of Al₂O₃ that may be deposited using an atomic layer deposition (ALD) process. The protective layer 214 may have a thickness in a range from approximately 5 nm to approximately 50 nm. Alternatively, the protective layer 214 may be formed of various other materials using other depositions processes and may have other thicknesses. The protective layer 214 may be configured to protect the color conversion material (202a, 202b, 202c) while allowing incident photons 204 to be transmitted through the protective layer 214 (e.g., see FIG. 2).

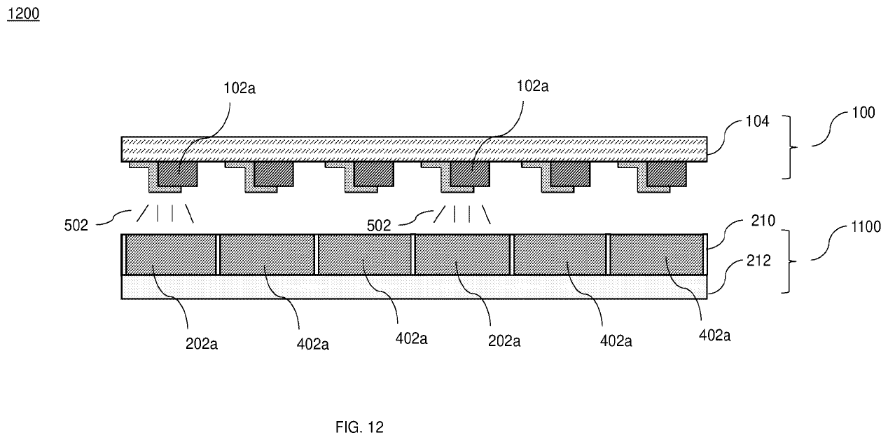

FIG. 11 is a vertical cross-sectional view of a further intermediate structure 1100 that may be used in the formation of a color conversion device 201 (e.g., see FIG. 2), according to a second embodiment. In this embodiment, a spin-coating process may be used to non-selectively deposit the first quantum dot ink 402a in all of the vias 302 in the intermediate structure 300 of FIG. 3. As described above, the first quantum dot ink 402a may include quantum dots having a first size and composition suspended in a photocurable polymer material. The first quantum dot ink 402a may exposed to blue light or UV radiation to thereby crosslink the first photocurable polymer material, as described in greater detail with reference to FIG. 12, below.

FIG. 12 is a vertical cross-sectional view of a further intermediate structure 1200 that may be used in the formation of a color conversion device 201 (e.g., see FIG. 2), according to the second embodiment. The intermediate structure 1200 may include an array of LEDs (e.g., intermediate structure 100 of FIG. 1) positioned over or under the intermediate structure 1100 of FIG. 11. The array of LEDs may be used as a manufacturing tool to selectively illuminate the first quantum dot ink 402a. As shown, a first plurality of LEDs 102a may be selectively turned on to expose the first (e.g., red) quantum dot ink 402a to blue light or UV radiation 502. In this way, the blue light or UV radiation 502 may cause the first quantum dot ink 402a in some vias 302 (e.g., in the vias located in the red subpixels) to become crosslinked (i.e., the photocurable polymer material of the ink to become crosslinked), thereby forming the first color conversion material 202a.

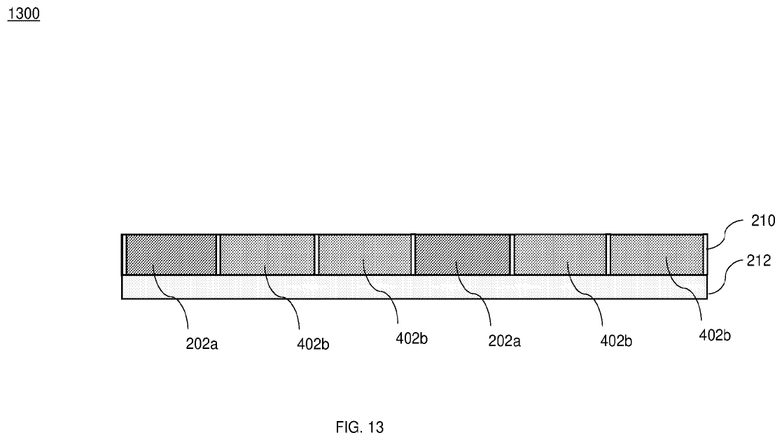

FIG. 13 is a vertical cross-sectional view of a further intermediate structure 1300 that may be used in the formation of a color conversion device 201 (e.g., see FIG. 2), according to the second embodiment. In this regard, portions of the first quantum dot ink 402a that were not illuminated in the intermediate structure 1200 (e.g., see FIG. 12) (e.g., red quantum dot ink located in green and blue subpixel vias 302) may be selectively removed because the photocurable polymer material of the ink in these vias 302 as not crosslinked by illumination.

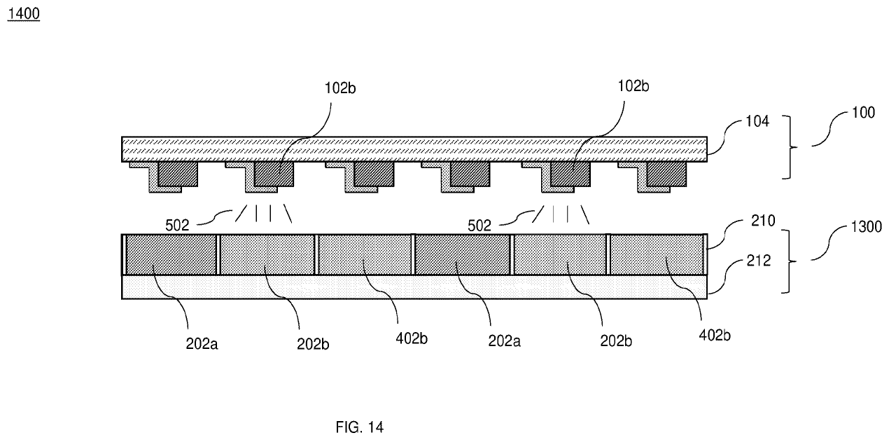

A spin-coating process may then be used to deposit a second (e.g., green) quantum dot ink 402b in the plurality of vias 302 that were not illuminated in the intermediate structure 1200 of FIG. 12 (i.e., in the vias that are not already filled by the first color conversion material 202a). As described above, the second quantum dot ink 402b may include quantum dots having a second size and composition different from the first size and/or composition, suspended in a photocurable polymer material. The second quantum dot ink 402b may exposed to blue light or UV radiation to thereby crosslink the second photocurable polymer material, as described in greater detail with reference to FIG. 14, below.

FIG. 14 is a vertical cross-sectional view of a further intermediate structure 1400 that may be used in the formation of a color conversion device 201 (e.g., see FIG. 2), according to the second embodiment. The intermediate structure 1400 may include an array of LEDs (e.g., intermediate structure 100 of FIG. 1) positioned over or under the intermediate structure 1300 of FIG. 13. The array of LEDs may be used as a manufacturing tool to selectively illuminate the second quantum dot ink 402b. As shown, a second plurality of LEDs 102b may be selectively turned on to expose the second quantum dot ink 402b to blue light or UV radiation 502. In this way, the blue light or UV radiation 502 may cause the second quantum dot ink 402b to become crosslinked, thereby forming the second color conversion material 202b in respective vias 302 (e.g., in the vias 302 located in the green subpixels).

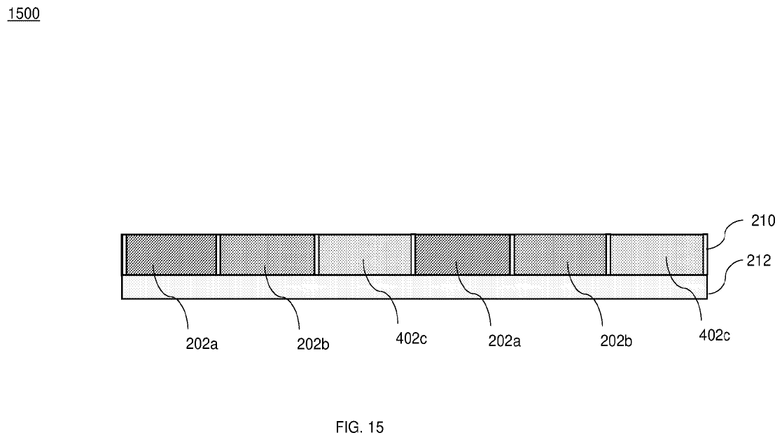

FIG. 15 is a vertical cross-sectional view of a further intermediate structure 1500 that may be used in the formation of a color conversion device 201 (e.g., see FIG. 2), according to the second embodiment. Portions of the second quantum dot ink 402b that were not illuminated in the intermediate structure 1400 (e.g., see FIG. 14) (and which were not crosslinked) may be selectively removed.

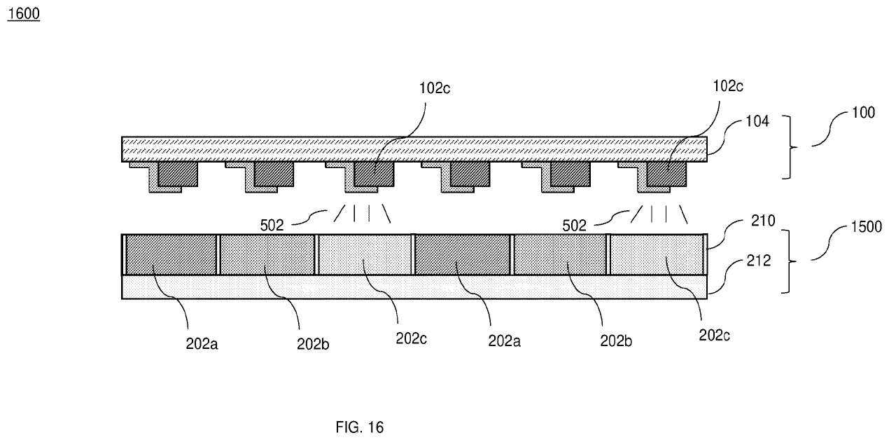

If the third color conversion material 202c is included in the final device 201 (e.g., if the LEDs 102 are UV LEDs), then a spin-coating process may then be used to deposit a third quantum dot ink 402c in the plurality of vias 302 that were not illuminated in the intermediate structure 1400 of FIG. 14 (i.e., in the 302 vias that are not already filled by the first and second color conversion materials 202a and 202b). As described above, the third quantum dot ink 402c may include quantum dots having a third size and composition different from the first and second size and/or composition, suspended in a photocurable polymer material. The third quantum dot ink 402c may exposed to blue light or UV radiation to thereby crosslink the second photocurable polymer material, as described in greater detail with reference to FIG. 16, below.

FIG. 16 is a vertical cross-sectional view of a further intermediate structure 1600 that may be used in the formation of a color conversion device 201 (e.g., see FIG. 2), according to the second embodiment. The intermediate structure 1600 may include an array of LEDs (e.g., intermediate structure 100 of FIG. 1) positioned over the intermediate structure 1500 of FIG. 15. The array of LEDs may be used as a manufacturing tool to selectively illuminate the third quantum dot ink 402c. As shown, a third plurality of LEDs 102c may be selectively turned on to expose the third quantum dot ink 402c to blue light or UV radiation 502. In this way, the blue light or UV radiation 502 may cause the third quantum dot ink 402c to become crosslinked, thereby forming the third color conversion material 202c (e.g., in the vias 302 located in the blue subpixels).

As mentioned above, the intermediate structure 300 of FIG. 3 may be formed in various ways in respective embodiments. For example, the substrate 212 and the matrix material having vias 302 formed therein may be formed by an injection molding process using a polymer material. In other embodiments described below, the substrate and the matrix material may be different materials.

FIG. 17 is a vertical cross-sectional view of a further intermediate structure 1700 that may be used in the formation of a color conversion device 201 (e.g., see FIG. 2), according to various embodiments. As shown in FIG. 17, the matrix material may include a positive-tone photosensitive polymer (i.e., the matrix material) 210L formed over a substrate 212. The substrate 212 may be a transparent polymer material that has sufficient mechanical strength to support the positive-tone photosensitive polymer 210L formed thereon.

FIG. 18 is a vertical cross-sectional view of a further intermediate structure 1800 that may be used in the formation of a color conversion device 201 (e.g., see FIG. 2), according to various embodiments. In this regard, the intermediate structure 1800 may include an array of LEDs (e.g., intermediate structure 100 of FIG. 1) positioned over or under the intermediate structure 1700 of FIG. 17. The array of LEDs may be used as a manufacturing tool to selectively illuminate exposed portions 210X of the positive-tone photosensitive polymer 210L.

As shown, all of the LEDs 102 may be tuned on to expose the exposed portions 210X to blue light or UV radiation 502. In this way, the blue light or UV radiation 502 may cause the exposed portions 210X of the positive-tone photosensitive polymer 210L to become crosslinked. The exposed portions 210X may then be removed by dissolution with a solvent. A plurality of unexposed portions 210U may remain after removal of the exposed portions 210X. In this way, the unexposed portions 210U of the matrix material become the matrix material walls 210 of the intermediate structure 300 of FIG. 3.

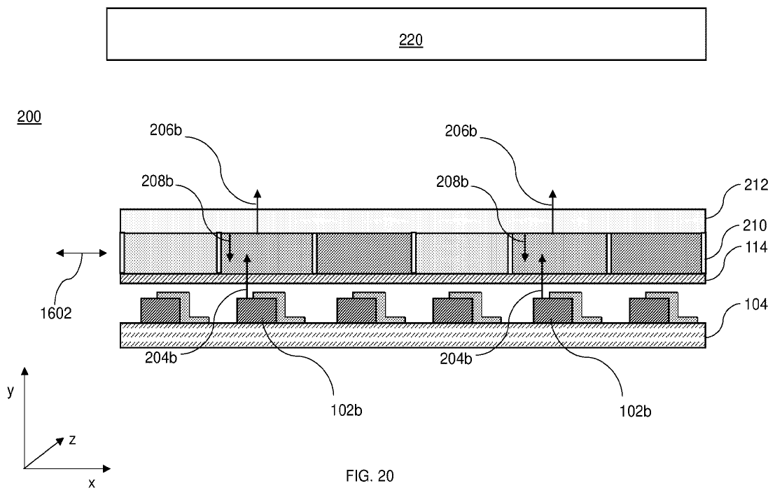

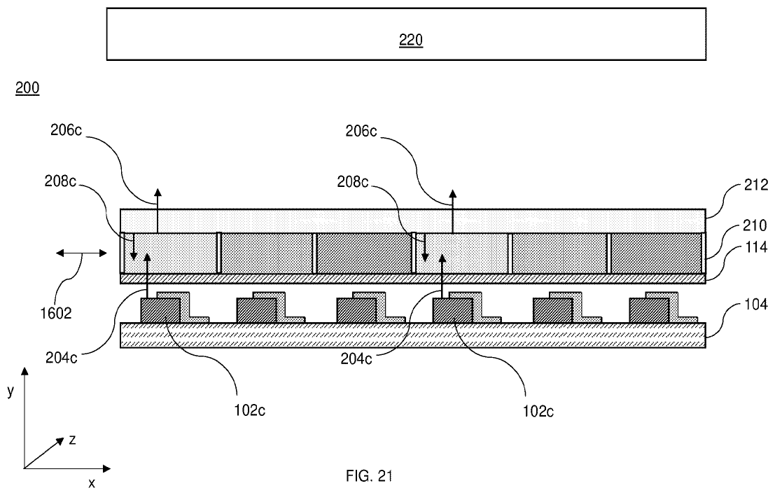

FIGS. 19-21 illustrate an alignment method between the LED array (e.g., the intermediate structure 100 of FIG. 1) and the free-standing color conversion device 201. FIG. 19 is a vertical cross-sectional view of a light emitting device 200 in a first configuration, FIG. 20 is a further vertical cross-sectional view of the light emitting device 200 in a second configuration, and FIG. 21 is a further vertical cross-sectional view of the light emitting device 200 in a third configuration, according to various embodiments. The light emitting device 200 may include an array of LEDs (e.g., intermediate structure 100 of FIG. 1) positioned over or under the color conversion device 201, which includes a color conversion material (202a, 202b, 202c).

As shown in FIG. 19, a first plurality of LEDs 102a may be turned on to generate first incident photons 204a that may be absorbed by the first color conversion material 202a to generate first converted photons 206a having a first color (e.g., red color). The first converted photons 206a may be detected with a photodetector (e.g., a spectrometer) 220 that is configured to measure an intensity of the first converted photons 206a.

According to an embodiment, a method of positioning the color conversion device 201 relative to the array of LEDs (e.g., intermediate structure 100 of FIG. 1) includes adjusting a position of the color conversion device 201 relative to the LEDs 102a to thereby maximize an intensity of the first converted photons 206a. The method may include determining a first maximum intensity of the first converted photons 206a as a first function of position of the color conversion device 201 relative to the first plurality of LEDs 102a along a first direction (e.g., x-direction) 1602 in a two dimensional plane (e.g., x-z plane) that is parallel to an interface between the color conversion device 201 and the substrate 104 (e.g., parallel to a surface of the protective layer 114). The method may further include determining a second maximum intensity of the first converted photons 206a as a second function of position of the color conversion device 201 relative to the first plurality of LEDs 102a along a second direction (e.g., the z-direction into the plane of FIG. 19) in the two dimensional plane (e.g., the x-z plane) that is parallel to the interface between the color conversion device 201 find the substrate 104.

As shown in FIG. 20, a second plurality of LEDs 102b may be turned on to generate second incident photons 204b that may be absorbed by the second color conversion material 202b to generate second converted photons 206b having a second color. The second converted photons 206b may be detected with the photodetector 220 that is configured to measure an intensity of the second converted photons 206b.

According to an embodiment, the method of positioning the color conversion device 201 relative to the array of LEDs may include further adjusting a position of the color conversion device 201 relative to the LEDs 102b to thereby maximize an intensity of the second converted photons 206b. The method may include determining a third maximum intensity of the second converted photons 206b as a third function of position of the color conversion device 201 relative to the second plurality of LEDs 102b along the first direction 1602 in the two dimensional plane that is parallel to an interface between the color conversion device 201 and the substrate 104 (e.g., parallel to a surface of the protective layer 114). The method may further include determining a fourth maximum intensity of the second converted photons 206b as a second function of position of the color conversion device 201 relative to the second plurality of LEDs 102b along the second direction (e.g., into the plane of FIG. 20) in the two dimensional plane that is parallel to the interface between the color conversion device 201 and the substrate 104.

As shown in FIG. 21, a third plurality of LEDs 102c may be turned on to generate third incident photons 204c that may be absorbed by the third color conversion material 202c to generate third converted photons 206c having a third color. The third converted photons 206c may be detected with a detector that is configured to measure an intensity of the third converted photons 206c.

According to an embodiment, the method of positioning the color conversion device 201 relative to the array of LEDs may include further adjusting a position of the color conversion device 201 relative to the LEDs 102c to thereby maximize an intensity of the third converted photons 206c. The method may include determining a fifth maximum intensity of the third converted photons 206c as a third function of position of the color conversion device 201 relative to the third plurality of LEDs 102c along the first direction 1602 in the two dimensional plane that is parallel to an interface between the color conversion device 201 and the substrate 104 (e.g., parallel to a surface of the protective layer 114). The method may further include determining a sixth maximum intensity of the third converted photons 206c as a second function of position of the color conversion device 201 relative to the third plurality of LEDs 102c along the second direction (e.g., into the plane of FIG. 21) in the two dimensional plane that is parallel to the interface between the color conversion device 201 and the substrate 104.

The above described method determines a first position, a second position, a third position, a fourth position, a fifth position, and a sixth position corresponding to the first maximum intensity, the second maximum intensity, the third maximum intensity, the fourth maximum intensity, the fifth maximum intensity, and the sixth maximum intensity, respectively. The first position, the second position, the third position, the fourth position, the fifth position, and the sixth position may then be averaged to determine an optimal position of the color conversion device 201 relative to the array of LEDs.

Alternatively, a first position may be determined that maximizes the intensity of the first color, a second position may be determined the maximizes the intensity of the second color, and a third position may be determined that maximizes the intensity of the third color. Each of the first position, the second position, and the third position may denote a relative two dimensional position of the color conversion device 201 relative to the plurality of LEDs. The optimal position of the color conversion device 201 may then be determined by averaging the first position, the second position and the third position. Thus, the two positions along two perpendicular directions in a plane determined for each color, may serve as two dimensional coordinates for the single point that maximizes the intensity of each color.

In further embodiments, the method may also include adjusting an orientation angle (not shown) of the color conversion device 201 relative to the array of LEDs. For example, for a fixed position in the two dimensional plane, the color conversion device 201 may be tilted relative to a plane (e.g., x-y plane) parallel to an interface between the color conversion device 201 and the substrate 104. An first orientation angle may be determined that maximizes an intensity of a first color of converted photons, a second orientation angle may be determined that maximizes an intensity of a second color of converted photons, and a third orientation angle may be determined that maximizes an intensity of a third color of converted photons. An optimum orientation of the color conversion device 201 relative to the array of LEDs may then be determined based on first orientation angle, the second orientation angle, and the third orientation angle.

After the free-standing color conversion device 201 is aligned relative to the array of LEDs 102 at the optimum position, the color conversion device 201 is attached to the array of LEDs 102 using an adhesive and/or mechanical attachment features (e.g., clamps, brackets, housing, etc.). Thus, the free-standing color conversion device 201 permits improved alignment to the LEDs 102 than if the layers of the color conversion device were deposited over the LEDs one by one, which would prevent the post manufacture alignment step.

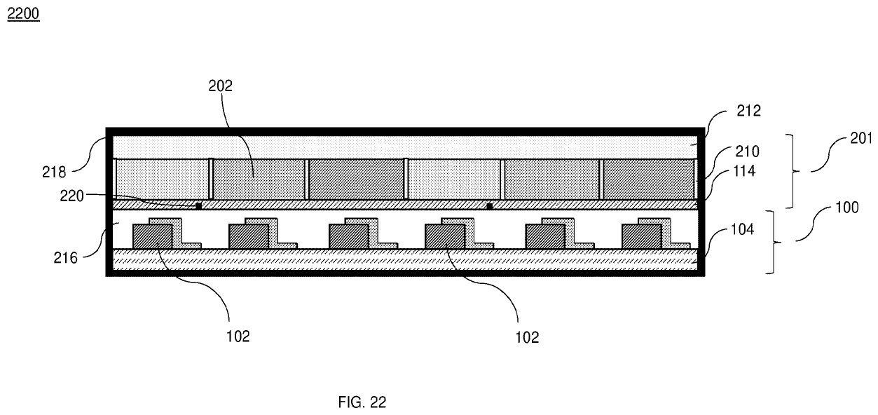

FIG. 22 is a vertical cross-sectional view of the packaged light emitting device 2200 in a one configuration, according to various embodiments. An optically transparent insulating fill material 216, such as silicon oxide or a polymer, may be formed between the LEDs 102. The light emitting device 2200 includes a housing (e.g., package) 218 which is transparent to visible light or has window in its upper portion which is transparent to visible light. The package 218 may comprise a polymer material. The package 218 holds the freestanding color conversion device 201 and the LED array 100 together after the optical alignment steps described above.

In one embodiment, alignment protrusions 220 may be used to assign in alignment of the free-standing color conversion device 201 and the LED array 100. The protrusions 220 may be located on the top surface of the LED array 100, and may be inserted into respective grooves in the bottom surface of the free-standing color conversion device 201 to form an interlocking pattern. Alternatively, the protrusions 220 may be located on the top surface of the free-standing color conversion device 201, and may be inserted into respective grooves in the bottom surface of the LED array 100. Alternatively, the protrusions are located in both surfaces and are inserted into opposing grooves in the opposing surfaces. The protrusions 220 may comprise any material, such as insulating, semiconductor or conductive material. For example, the protrusions may comprise protruding portions of the insulating fill material 216 and/or in the protective layer 214. The grooves may be formed in the protective layer 214 and or in the insulating fill material 216.

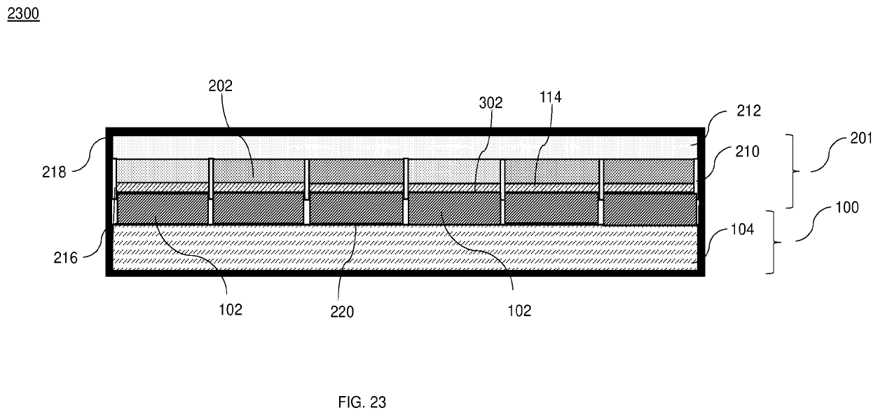

In a packaged device 2300 of an alternative embodiment shown in FIG. 23, instead of using dedicated alignment protrusions 220 and corresponding grooves, the LEDs 102 themselves may be used as alignment features by fitting into grooves in the free-standing color conversion device 201. The grooves may be located in the protective layer 214 and/or in the color conversion material 202. For example, the color conversion material 202 may be underfilled in the vias 302 to leave grooves over the color conversion material 202 between the matrix material walls 210. The protective layer 214 may partially fill the grooves and leave the remaining portions of the grooves to be filled with the LEDs 102. Thus, the grooves in this embodiment comprise the unfilled portions of the above described vias 302.

The preceding description of the disclosed embodiments is provided to enable persons of ordinary skill in the art to make or use the disclosed embodiments. Various modifications to these embodiments will be readily apparent to those of ordinary skill in the art, and the generic principles defined herein may be applied to other embodiments without departing from the spirit or scope of the disclosure. Thus, the disclosure is not intended to be limited to the embodiments shown herein but is to be accorded the widest scope consistent with the following claims and the principles and novel features disclosed herein.

What is claimed is:

1. A method of forming a light emitting device, comprising:
providing a free standing support comprising a matrix material containing first and second vias;
depositing in the first vias in the matrix material a first photocurable quantum dot ink comprising a first plurality of quantum dots suspended in a first photocurable polymer material;
illuminating the first photocurable quantum dot ink with ultraviolet radiation or blue light from first light emitting diodes of an array of light emitting diodes to crosslink the first photocurable polymer material in the first vias;
depositing in the second vias in the matrix material a second photocurable quantum dot ink comprising a second plurality of quantum dots suspended in a second photocurable polymer material, wherein the second plurality of quantum dots are configured to emit light of a different peak wavelength than the first plurality of quantum dots;
illuminating the second photocurable quantum dot ink with ultraviolet radiation or blue light from second light emitting diodes of the array of light emitting diodes to crosslink the second photocurable polymer material in the second vias: and
attaching the free standing support to the array of light emitting diodes after the steps of illuminating the first and the second photocurable quantum dot ink.

2. The method of claim 1, wherein the matrix material further comprises third vias.

3. The method of claim 2, further comprising:
depositing in the third vias in the matrix material third photocurable quantum dot ink comprising third plurality of quantum dots suspended in a third photocurable polymer material, wherein the third plurality of quantum dots are configured to emit light of a different peak wavelength than the first and the second plurality of quantum dots; and
illuminating the third photocurable quantum dot ink with ultraviolet radiation or blue light from third light emitting diodes of the array of light emitting diodes to crosslink the third photocurable polymer material in the third vias prior to the step of attaching.

4. The method of claim 3, further comprising forming the first vias, the second vias, and the third vias in a single via formation operation.

5. The method of claim 4, wherein the matrix material, including the first vias, the second vias, and the third vias is formed by injection molding, and wherein the matrix material comprises a polymer material.

6. The method of claim 3, wherein the matrix material comprises a positive-tone photosensitive polymer formed over a first substrate.

7. The method of claim 6, further comprising:
selectively illuminating first portions, second portions, and third portions of the positive-tone photosensitive polymer with the respective first, second and third light emitting diodes of the array of light emitting diodes to form un-crosslinked polymer material respectively in the first portions, the second portions, and the third portions of the matrix material; and
removing the un-crosslinked polymer material respectively in the first portions, the second portions, and the third portions to form the first vias, the second vias, and the third vias.

8. The method of claim 3, wherein:
the step of depositing in the first vias in the matrix material the first photocurable quantum dot ink comprises selectively depositing the first photocurable quantum dot ink only in the first vias;
the step of depositing in the second vias in the matrix material the second photocurable quantum dot ink comprises selectively depositing the second photocurable quantum dot ink only in the second vias after the step of illuminating the first photocurable quantum dot ink; and
the step of depositing in the third vias in the matrix material the third photocurable quantum dot ink comprises selectively depositing the third photocurable quantum dot ink only in the third vias after the step of illuminating the second photocurable quantum dot ink.

9. The method of claim 3, wherein:
the step of depositing in the first vias in the matrix material the first photocurable quantum dot ink comprises non-selectively depositing the first photocurable quantum dot ink in the first, the second and the third vias, followed by removing un-crosslinked portions of the first photocurable quantum dot ink from the second and the third vias after the step of illuminating the first photocurable quantum dot ink;
the step of depositing in the second vias in the matrix material the second photocurable quantum dot ink comprises non-selectively depositing the second photocurable quantum dot ink in the second and the third vias, followed by removing un-crosslinked portions of the second photocurable quantum dot ink from the third vias after the step of illuminating the second photocurable quantum dot ink; and
the step of depositing in the third vias in the matrix material the third photocurable quantum dot ink comprises depositing the third photocurable quantum dot ink in the third vias, after the step of illuminating the third photocurable quantum dot ink.

10. The method of claim 1, further comprising forming a protective layer over the color conversion device.

11. The method of claim 1, wherein the free standing support containing the first and the second quantum dots comprises a color conversion device.

12. The method of claim 11, further comprising:
forming protrusions in a mating surface of at least one of the color conversion device and the array of light emitting diodes;
forming recesses in the mating surface of at least one of the color conversion device and the array of light emitting diodes; and
attaching the color conversion device to the array of light emitting diodes such that the protrusions are inserted into the respective grooves to form an interlocking pattern to align the color conversion device and the array of light emitting diodes.

13. The method of claim 11, wherein:
the first and the second of vias are partially filled with the crosslinked first and second photocurable polymer material to leave grooves; and
the array of LEDs comprise protrusions which are inserted into the respective grooves to form an interlocking pattern to align the color conversion device and the array of light emitting diodes.

14. A method of forming a light emitting device, comprising:
providing a plurality of light emitting diodes on a substrate such that the plurality of light emitting diodes is configured to emit blue light or ultraviolet radiation incident photons;
providing a color conversion device comprising a color conversion material formed in a plurality of vias in a matrix material;
positioning the color conversion device relative to the plurality of light emitting diodes such that each of the plurality of vias is located over a corresponding one of the plurality of light emitting diodes, wherein the color conversion material in each of the plurality of vias is configured to absorb the incident photons from the corresponding one of the plurality of light emitting diodes and to generate converted photons having a longer peak wavelength than a peak wavelength of the incident photons; and
adjusting a position of the color conversion device relative to the plurality of light emitting diodes to thereby maximize an intensity of the converted photons having the longer peak wavelength.

15. The method of claim 14, wherein the step of adjusting the position of the color conversion device relative to the plurality of light emitting diodes further comprises:
determining a first maximum intensity of converted photons as a first function of position of the color conversion device relative to the plurality of light emitting diodes along a first direction in a two dimensional plane that is parallel to an interface between the color conversion device and the substrate;
determining a second maximum intensity of converted photons as a second function of position of the color conversion device relative to the plurality of light emitting diodes along a second direction in the two dimensional plane that is parallel to the interface between the color conversion device and the substrate; and
determining a maximum intensity of converted photons as a function of an orientation angle of the color conversion device relative to the plurality of light emitting diodes in a two dimensional plane that is parallel to an interface between the color conversion device and the substrate.

16. A light emitting device, comprising:
a substrate:
a plurality of light emitting diodes located on the substrate and configured to emit blue or ultraviolet radiation incident photons; and
a color conversion device comprising a color conversion material located in a plurality of vias in a matrix material,
wherein each of the plurality of vias is located over a corresponding one of the plurality of light emitting diodes such that the color conversion material in each of the plurality of vias is configured to absorb the incident photons from the corresponding one of the plurality of light emitting diodes and to generate converted photons having a longer peak wavelength than a peak wavelength of the incident photons, and
wherein the color conversion device is a free standing structure that is attached over the plurality of light emitting diodes.

17. The light emitting device of claim 16, wherein:
each of the plurality of light emitting diodes comprises a width of 10 microns or less and adjacent light emitting diodes are separated by a distance of 1 micron or less;
the color conversion material comprises quantum dots;
the quantum dots are configured to absorb the incident photons and to emit the converted photons having a color that is one of red, green, or blue; and
the plurality of vias in the matrix material are arranged in an ordered array of pixels with each pixel comprising a red subpixel, a green subpixel, and a blue subpixel such that the color conversion material in respective subpixels is configured to respectively generate red, green, and blue converted photons.

18. The light emitting device of claim 16, wherein:
at least one of the color conversion device and plurality of light emitting diodes contains protrusions in a mating surface;
at least one of the color conversion device and plurality of light emitting diodes contains grooves in the mating surface; and
the protrusions are inserted into the respective grooves to form an interlocking pattern to align the color conversion device and the plurality of light emitting diodes.

19. The light emitting device of claim 16, wherein:
the plurality of vias are partially filled with the color conversion material to leave grooves; and
the plurality of LEDs comprise protrusions which are inserted into the respective grooves to form an interlocking pattern to align the color conversion device and the plurality of light emitting diodes.

20. The light emitting device of claim 16, wherein the color conversion device and plurality of light emitting diodes are held together by at least one of an adhesive or a mechanical attachment feature.
